(19) United States
(12) Patent Application Publication
(10) Pub. No.: US 2022/0360046 A1
(43) Pub. Date: Nov. 10, 2022

(54) Variable Wavelength Laser and Control Method Therefor

(71) Applicant: Nippon Telegraph and Telephone Corporation, Tokyo (JP)

(72) Inventor: Makoto Shimokozono, Tokyo (JP)

(21) Appl. No.: 17/619,721

(22) PCT Filed: Jul. 3, 2019
(86) PCT No.: PCT/JP2019/026493

§ 371 Date: Dec. 16, 2021

(51) Int. Cl. H01S 5/125; H01S 5/0625; H01S 5/062

(52) U.S. Cl. CPC H01S 5/125; H01S 5/06256; H01S 5/06246

(57) ABSTRACT

A first current injection unit that injects a DBR current into a rear DBR region and a front DBR region and a second current injection unit that injects a phase adjustment current into a phase adjustment region are included. The second current injection unit injects the phase adjustment current that changes at a frequency that is twice as much as that of the DBR current into the phase adjustment region in synchronization with the DBR current. The first current injection unit inverts the DBR current to a positive value in a region in which the DBR current is a negative value.

### CROSS-REFERENCE TO RELATED APPLICATIONS

This application is a national phase entry of PCT Application No. PCT/JP2019/026493, filed on Jul. 3, 2019, which application is hereby incorporated herein by reference.

### TECHNICAL FIELD

The present invention relates to a wavelength-variable laser formed by a semiconductor laser of which wavelength is variable and a method for manufacturing the same.

### BACKGROUND

Wavelength-variable lasers are useful light sources used in a wide range of fields such as wavelength division multiplexing transmission, optical measurement, optical frequency sweeping optical coherence tomography (OCT), laser light spectroscopy, and light sensitivity measurement. Among the above, a wavelength-variable semiconductor laser using a semiconductor as a gain medium has low power consumption, is small in size, and is easy to handle, and hence is widely used in various fields.

Wavelength-variable semiconductor lasers are mainly divided into three types due to differences in structure. The three types means a distributed feedback (DFB) laser, a distributed bragg reflector (DBR) laser, and an external cavity laser.

The DFB laser includes a grating (diffraction grating) on an active layer and realizes wavelength change by adjusting the injection current amount or the temperature of a device.

In the DBR laser, a grating is not disposed on an active region, and a DBR grating is disposed on both sides or one side of the active region. In general, the DBR laser includes a phase adjustment region for performing phase matching. The DBR laser achieves variation of the wavelength with use of a carrier plasma effect that occurs by injecting current into a DBR region that is independent of the active region.

The external cavity laser enables the wavelength to be variable by disposing a mirror on the outer side of an active region and mechanically moving the mirror. In the case of the semiconductor laser, a mirror obtained by micro-electromechanical systems (MEMS) is normally used in order to reduce the footprint (device size).

Next, features of those lasers when those lasers are applied to gas sensing are described. The laser that is most used for gas sensing is the DFB laser. The DFB laser has a structure that can realize a narrow linewidth, and hence is used in a form in which the wavelength is aligned with the absorption line of gas. As described above, in the DFB laser, the wavelength can be variable in a range of about 1 nm by changing the injection current and the temperature of the device itself. However, it takes 1 ms or more for the DFB laser to perform sweeping when wavelength sweeping is performed.

The DBR laser can cause a wavelength of about 5 nm to be variable by simultaneously changing the DBR current and the phase adjustment current. The DBR laser causes the wavelength to be variable by using a refractive index change induced by the injection current as a principle, and hence can enable the wavelength to be variable at a high speed, that is, in microseconds or less.

The external cavity laser is characterized by a wideband wavelength-variable width acquired by using a MEMS mirror, and can enable the wavelength to be variable to the extent of 100 nm in principle. However, when a semiconductor is used as the gain medium, the wavelength is variable by about 60 nm in actuality because the gain band is limited. In the external cavity laser, the MEMS mirror is mechanically moved, and hence the wavelength sweeping requires about milliseconds.

In consideration of the above, the DBR laser that can enable the wavelength to be variable with a higher speed is conceived to be suitable for gas sensing. In the abovementioned type of sensing, it is preferred that the range by which the wavelength is variable be wider. For example, in the DBR laser, a state in which the wavelength is continuously variable by 5 nm or more is realized (see NPL 1). In the technology above, the same power source is resistively divided, and currents are synchronized and injected into the DBR region and the phase adjustment region of the DBR laser, to thereby enable the wavelength to be variable by 5.6 nm. In NPL 2, control is performed by separate power sources in which the DBR current and the phase adjustment current of the DBR laser are synchronized with each other. The control method of NPL 1 and the control method of NPL 2 are essentially the same.

### CITATION LIST

Non Patent Literature
NPL 1—T. Kanai et al., “First Demonstration of 2 μm Wavelength-variable Distributed Bragg Reflector Laser Diode”, International Semiconductor Laser Conference, TuB4, 2016.
NPL 2—M. Abe et al., “4-nm continuous rapid sweeping spectroscopy in 2-μm band using distributed Bragg reflector laser”, Applied Physics B, 123:260, 2017.

### SUMMARY

### Technical Problem

The structure of a wavelength-variable laser according to a DBR laser is described with reference to FIG. 5. In the wavelength-variable laser, a rear DBR region 321, a phase adjustment region 322, a laser active region 323, a front DBR region 324, and an amplification region 325 are arranged in the waveguide direction.

The regions share a semiconductor substrate 301. In the rear DBR region 321 and the phase adjustment region 322, a core 302 formed by a bulk semiconductor is formed on the semiconductor substrate 301. In the rear DBR region 321, a grating 303 is formed on the core 302.

In the laser active region 323, an active layer 304 having a multi-quantum well structure is formed on the semiconductor substrate 301.

In the front DBR region 324, a core 305 formed by a bulk semiconductor is formed on the semiconductor substrate 301, and a grating 306 is formed on the core 305.

In the amplification region 325, an active layer 307 having a multi-quantum well structure is formed on the semiconductor substrate 301.

An overclad 308 is formed in the regions in a sharing manner.

A common electrode 310 is formed on the rear side of the semiconductor substrate 301. A first electrode 311 is formed on the overclad 308 in the rear DBR region 321. A second electrode 312 is formed on the overclad 308 in the phase adjustment region 322. A third electrode 313 is formed on the overclad 308 in the laser active region 323. A fourth electrode 314 is formed on the overclad 308 in the front DBR region 324. A fifth electrode 315 is formed on the overclad 308 in the amplification region 325.

Next, the roles of the regions when laser oscillation and wavelength control are performed are described. Light generated in the laser active region 323 by injecting a current 333 into the third electrode 313 causes laser oscillation by a resonator formed by the rear DBR region 321, the phase adjustment region 322, and the front DBR region 324. The laser is amplified by the amplification region 325 in which a current 334 is injected into the fifth electrode 315, and exits from the right side of the paper of FIG. 5. The oscillation wavelength is determined by the resonator formed by the front DBR region 324 and the rear DBR region 321 in which a current 331 is injected into the first electrode 311 and the fourth electrode 314, and the phase adjustment region 322 in which a current 332 is injected into the second electrode 312.

Next, a wavelength map is described. FIG. 6 shows an example of a wavelength map of the wavelength-variable laser according to the DBR laser. In the wavelength map regarding the wavelength-variable laser, the horizontal axis represents the current injected into the DBR region and the vertical axis represents the current injected into the phase adjustment region, and oscillation wavelength ranges acquired by the combination of those two currents are expressed by regions of which display states are distinguishably different from each other. In the example shown in FIG. 6, the regions are distinguished by allocating letters (alphabet letters) to the regions. The distinguishment of the regions can be carried out by colors. The DBR current herein is the total current amount that flows when the front DBR region and the rear DBR region are electrically connected.

In the wavelength map, a mode hop does not occur in regions in which the state continuously changes, but a mode hop is generated when a borderline at which the wavelength discontinuously changes is crossed. The following can be understood from the wavelength map. Firstly, it is also possible to enable the wavelength to be variable to a certain degree by injecting a current only into the DBR region. Secondly, it is also possible to enable the wavelength to be variable to a certain degree by injecting a current only into the phase adjustment region, but the oscillation wavelength can only be continuously changed within a range of about 1 nm at most because a mode hop immediately occurs.

However, when current is applied by interposing division resistors between the DBR region and the phase adjustment region as described in NPL 1 or when current is applied in a form in which separate power sources are in synchronization with each other as described in NPL 2, a wavelength of 5 nm or more can be continuously changed along a locus indicated by an arrow view line in FIG. 6.

Next, a side-mode suppression ratio (SMSR) map is described. The side-mode suppression ratio is a parameter indicating the monochromaticity (the unity of the longitudinal mode) of the spectrum of the laser that oscillates and is a strength ratio between the highest peak (main mode) of which spectral intensity is the largest and the second highest peak (side mode).

FIG. 7 shows an example of an SMSR map of the wavelength-variable laser according to the DBR laser. In the map, with regard to the abovementioned wavelength-variable laser, the horizontal axis represents the current injected into the DBR region, the vertical axis represents the current injected into the phase adjustment region, and the SMSR of the oscillation light emitted by the combination of those two currents is represented by regions of which display states are distinguishably different from each other. In the example shown in FIG. 7, the regions are distinguished by allocating letters (alphabet letters) to the regions. The distinguishment of the regions can be carried out by colors.

When a locus (the arrow view line in FIG. 7) is drawn with the same conditions as those in FIG. 6, it can be seen that the locus partially passes through points with poor SMSR. In other words, in the related art described above, control can be performed relatively easily, but a state with excellent SMSR cannot always be maintained because control is linearly performed on the wavelength map as indicated by the arrow view line. Therefore, in the related art (oscillation control), there has been a problem in that the locus passes through places with poor SMSR, and hence the state of the oscillation may become unstable and a mode hop is generated at worst.

The abovementioned phenomenon is described from the viewpoint of electric signals with reference to FIG. 8A and FIG. 8B. FIG. 8A and FIG. 8B show an electrically controlling method according to a conventional method in more detail. In FIG. 8A, the horizontal axis represents time (or phase), and the vertical axis represents the intensity of the modulation signal. When the DBR current and the phase adjustment current modulated by modulation signals of the same frequency and the same phase shown in FIG. 8A are applied to the DBR laser, the locus drawn in accordance with the relationship between the DBR current and the phase adjustment current forms a straight line as shown in FIG. 8B. The line corresponds to a so-called Lissajous figure.

A locus for a case where the current widths are the same is drawn in FIG. 8A and FIG. 8B. However, when the slope of the straight line is desired to be changed, the ratio between the DBR current and the phase adjustment current only needs to be changed. When the location in which the locus is drawn is desired to be shifted, a bias current only needs to be applied. As described above, the locus in which the relationship between the DBR current and the phase adjustment current is drawn in a form of a straight line is not in accordance with the form of the wavelength map. Therefore, places with poor SMSR are generated.

Embodiments of the present invention have been made in order to solve the problem as above, and an object thereof is to suppress the degradation of the SMSR in a wavelength-variable laser.

### Means for Solving the Problem

A wavelength-variable laser according to embodiments of the present invention includes: a rear DBR region; a phase adjustment region disposed following the rear DBR region; a laser active region disposed following the phase adjustment region; a front DBR region disposed following the laser active region; an amplification region disposed following the front DBR region; a first current injection unit that injects a DBR current into the rear DBR region and the front DBR region; and a second current injection unit that injects a phase adjustment current that changes at a frequency that is twice as much as a frequency of the DBR current into the phase adjustment region in synchronization with the DBR current.

A control method of a wavelength-variable laser according to embodiments of the present invention is a control method of a wavelength-variable laser including: a rear DBR region; a phase adjustment region disposed following the rear DBR region; a laser active region disposed following the phase adjustment region; a front DBR region disposed following the laser active region; and an amplification region disposed following the front DBR region, the control method including injecting a phase adjustment current that changes at a frequency that is twice as much as a frequency of a DBR current injected into the rear DBR region and the front DBR region into the phase adjustment region in synchronization with the DBR current.

### Effects of Embodiments of the Invention

As described above, according to embodiments of the present invention, the phase adjustment current that changes at a frequency that is twice as much as the frequency of the DBR current injected into the rear DBR region and the front DBR region is injected into the phase adjustment region in synchronization with the DBR current, and hence the degradation of the SMSR in the wavelength-variable laser is suppressed.

### BRIEF DESCRIPTION OF THE DRAWINGS

FIG. 1 is a configuration diagram illustrating the configuration of a wavelength-variable laser according to an embodiment of the present invention.

FIG. 2A is a characteristic diagram showing the change of a modulation signal of a DBR current and a modulation signal of a phase adjustment current with respect to time change of the wavelength-variable laser according to the present invention.

FIG. 2B is a characteristic diagram showing the relationship between the DBR current and the phase adjustment current of the wavelength-variable laser according to the present invention.

FIG. 3A is a characteristic diagram showing the change of a DBR current and a phase adjustment current with respect to time change of a conventional wavelength-variable laser.

FIG. 3B is a characteristic diagram showing the relationship between the DBR current and the phase adjustment current of the conventional wavelength-variable laser.

FIG. 4A is a characteristic diagram showing the change of the DBR current and the phase adjustment current with respect to time change of the wavelength-variable laser according to the embodiment.

FIG. 4B is a characteristic diagram showing the relationship between the DBR current and the phase adjustment current of the wavelength-variable laser according to the embodiment.

FIG. 5 is a cross-sectional view illustrating the configuration of a wavelength-variable laser according to a DBR laser.

FIG. 6 is computer graphics showing an oscillation wavelength map of the wavelength-variable laser according to the DBR laser.

FIG. 7 is computer graphics showing an SMSR map of the wavelength-variable laser according to the DBR laser.

FIG. 8A is a characteristic diagram showing the change of a modulation signal of a DBR current and a modulation signal of a phase adjustment current with respect to time change.

FIG. 8B is a characteristic diagram showing the relationship between the DBR current and the phase adjustment current.

### DETAILED DESCRIPTION OF ILLUSTRATIVE EMBODIMENTS

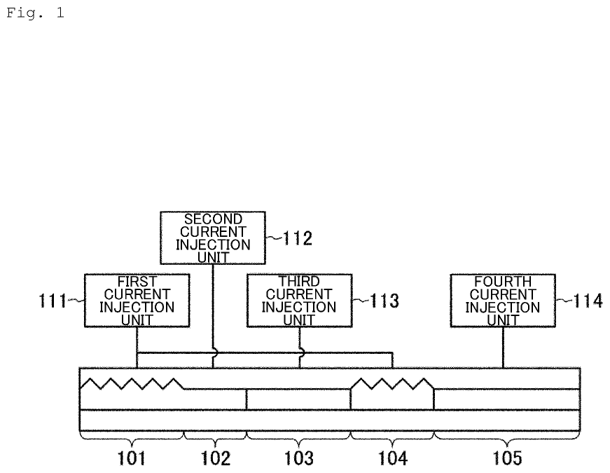

A wavelength-variable laser according to an embodiment of the present invention is described below with reference to FIG. 1. The wavelength-variable laser includes a rear DBR region 101, a phase adjustment region 102 disposed following the rear DBR region 101, a laser active region 103 disposed following the phase adjustment region 102, a front DBR region 104 disposed following the laser active region 103, and an amplification region 105 disposed following the front DBR region 104.

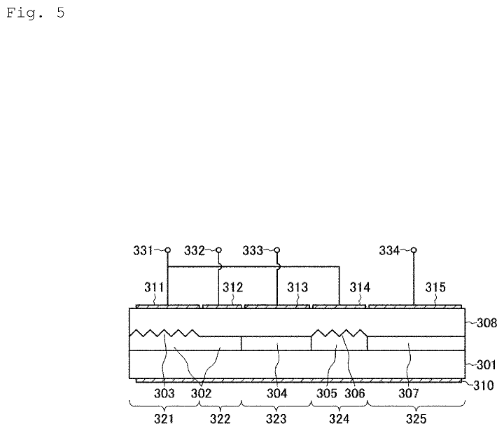

The regions are formed so as to share a semiconductor substrate. In the rear DBR region 101 and the phase adjustment region 102, a core formed by a bulk semiconductor is formed on the semiconductor substrate. In the rear DBR region 101, a grating is formed on the core. In the laser active region 103, an active layer having a multi-quantum well structure is formed on the semiconductor substrate. In the front DBR region 104, a core formed by a bulk semiconductor is formed on the semiconductor substrate, and a grating is formed on the core. In the amplification region 105, an active layer having a multi-quantum well structure is formed on the semiconductor substrate. An overclad is formed in the regions in a sharing manner. Those configurations are similar to those of the wavelength-variable laser according to the DBR laser described with reference to FIG. 5.

The wavelength-variable laser includes a first current injection unit 111 that injects a DBR current into the rear DBR region 101 and the front DBR region 104, and a second current injection unit 112 that injects a phase adjustment current to the phase adjustment region 102. The first current injection unit 111 applies a DBR current obtained by modulating the bias current by a modulation signal to the DBR regions. The second current injection unit 112 injects a phase adjustment current obtained by modulating the bias current by a modulation signal. The first current injection unit 111 inverts the modulation signal in regions in which the modulation signal is a negative value. The wavelength-variable laser includes a third current injection unit 113 that injects a current into the laser active region 103 and a fourth current injection unit 114 that injects a current into the amplification region 105.

Light generated in the laser active region 103 by injecting a predetermined current into the laser active region 103 by the third current injection unit 113 causes laser oscillation by a resonator formed by the rear DBR region 101, the phase adjustment region 102, and the front DBR region 104. The light is amplified by the amplification region 105 into which a predetermined current is injected by the fourth current injection unit 114, and exits from the right side of the paper of FIG. 1. The oscillation wavelength is determined by the DBR current injected by the first current injection unit 111 and the phase adjustment current injected by the second current injection unit 112.

In the wavelength-variable laser according to the embodiment, the second current injection unit 112 injects a phase adjustment current that changes at a frequency that is twice as much as that of the DBR current into the phase adjustment region 102 in synchronization with the DBR current. The first current injection unit 111 inverts the modulation signal for modulating the DBR current to a positive value in regions in which the modulation signal is a negative value.

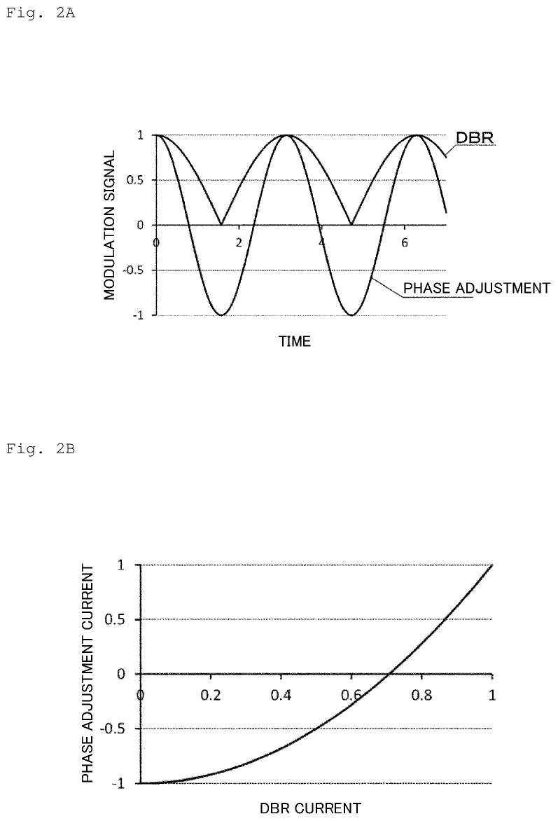

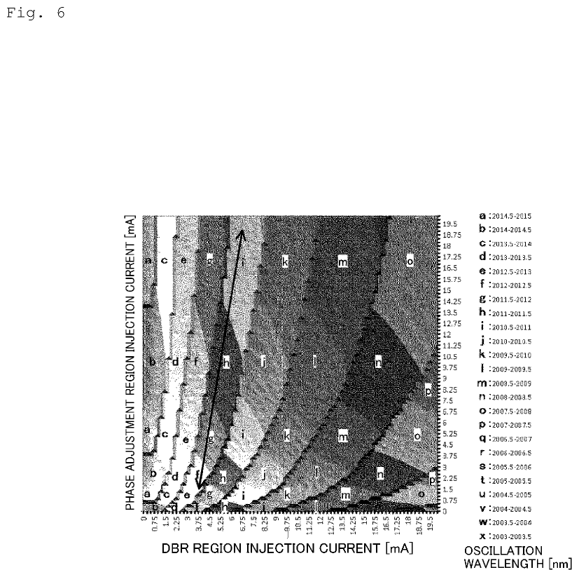

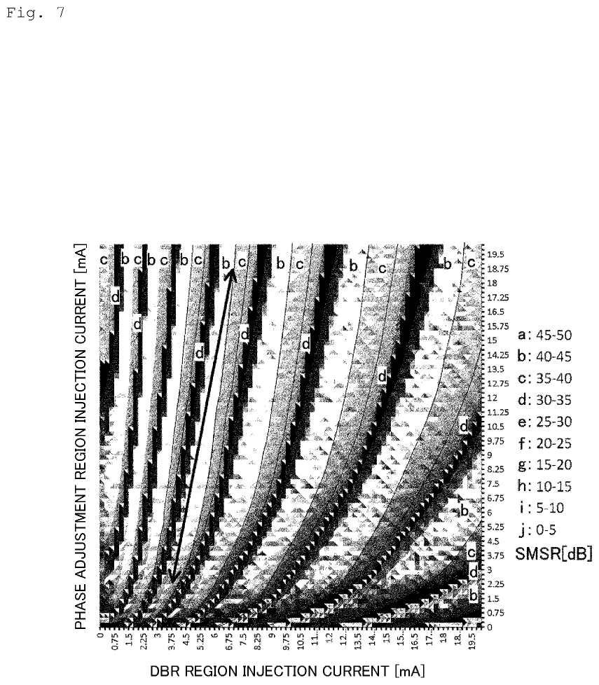

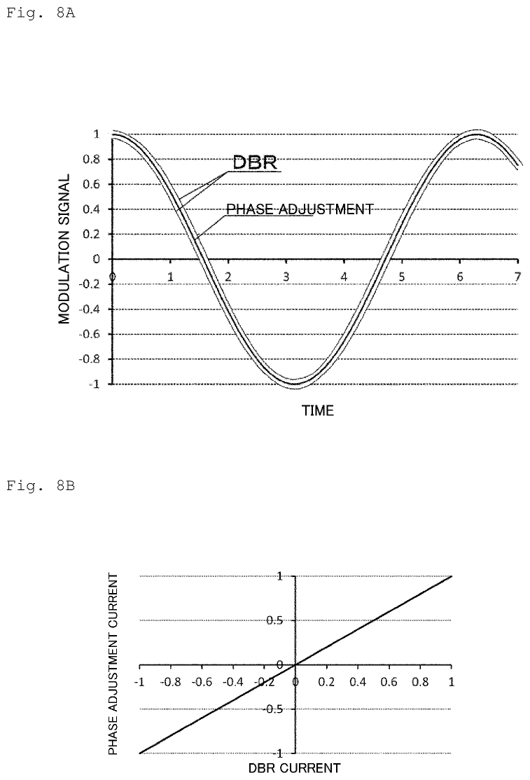

The abovementioned control is described with reference to FIG. 2A and FIG. 2B. The horizontal axis in FIG. 2A represents time (or phase). The vertical axis in FIG. 2A represents the intensity of the modulation signals. As shown in FIG. 2A, for the regions in which the modulation signal of the DBR current is a negative value, the modulation signal is inverted, and the modulation signal of the phase adjustment current is changed at a frequency that is twice as much as the modulation signal of the DBR current. By controlling (the modulation signals of) the currents as above, a locus drawn when the horizontal axis represents the DBR current and the vertical axis represents the phase adjustment current becomes a locus as that shown in FIG. 2B. By controlling the modulation signal of the DBR current and the modulation signal of the phase adjustment current, sweeping in a form along the form of the wavelength map (see FIG. 6) becomes possible, and the degradation of the SMSR can be suppressed. As described above, when the degradation of the SMSR can be suppressed, the oscillation of the laser light becomes possible with a higher signal-to-noise ratio (S/N).

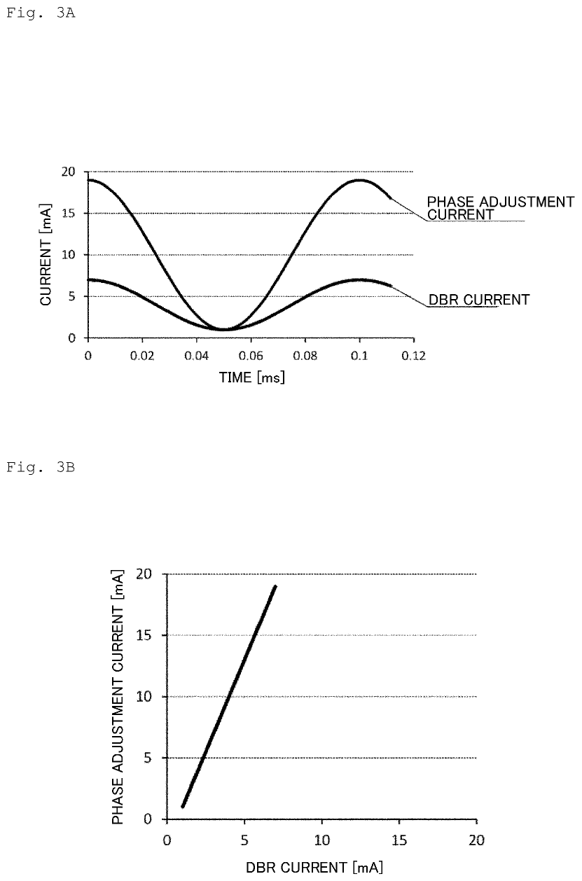

Next, the conventional control and the control of embodiments of the present invention are described in comparison with each other. First, the conventional control is described with reference to FIG. 3A and FIG. 3B. In the wavelength-variable semiconductor laser having a DBR structure, a current of 100 mA is applied to the laser active region and a current of 100 mA is applied to the amplification region. Periodically changing currents as those shown in FIG. 3A are applied to the DBR regions and the phase control region. As shown by the relationship in FIG. 3A, the DBR current and the phase adjustment current that change in the same phase with respect to time are applied. Specifically, the bias current is set to 4 mA and the amplitude is set to 3 mA for the DBR current, the bias current is set to 10 mA and the amplitude is set to 9 mA for the phase adjustment current, and oscillation is performed by a cosine wave with a period 0.1 ms. The locus described by the DBR current and the phase adjustment current set as described above forms a straight line as shown in FIG. 3B. When the SMSR of the laser oscillation light at this time is measured, the worst value is 20 dB.

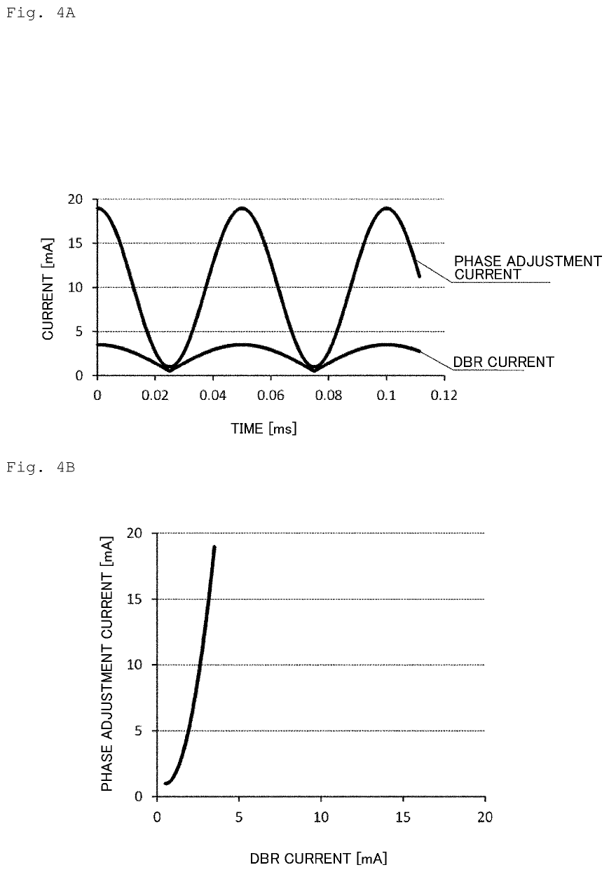

Next, embodiments of the present invention are described with reference to FIG. 4A and FIG. 4B. In the wavelength-variable semiconductor laser having a DBR structure, a current of 100 mA is applied to the laser active region and a current of 100 mA is applied to the amplification region. Periodically changing currents as those shown in FIG. 4A are applied to the DBR regions and the phase control region. Specifically, with respect to time, for the DBR current, the bias current is set to 0.5 mA, the amplitude is set to 3 mA, oscillation is performed by a cosine wave with a period of 0.1 ms, and then the modulation signal is inverted for the part where the phase is from 90° to 270°. For the phase adjustment current, the bias current is set to 10 mA, the amplitude is set to 9 mA, and oscillation is performed by a cosine wave with a period of 0.051 m.

The locus described by the DBR current and the phase adjustment current set as described above forms a curved line as shown in FIG. 4B. When the SMSR of the laser oscillation light at this time is measured, the worst value is 40 dB. Therefore, according to embodiments of the present invention, usage as a light source in which the wavelength is continuously variable becomes possible in addition to sufficiently ensuring the S/N ratio of the signal. Therefore, the absorption lines of a plurality of gas can be accurately detected by using the wavelength-variable laser according to embodiments of the present invention. In the description of the abovementioned embodiment, cosine waves are applied to the DBR regions and the phase control region. However, the same effect can be obtained even if other waveforms such as a triangle wave or a sawtooth wave are applied thereto as long as the relationship between the phase and the amplitude is the same because the locus drawn by the DBR current and the phase adjustment current does not change.

As described above, according to embodiments of the present invention, the phase adjustment current that changes at a frequency that is twice as much as that of the DBR current injected into the rear DBR region and the front DBR region is injected into the phase adjustment region in synchronization with the DBR current, and hence the degradation of the SMSR in the wavelength-variable laser is suppressed.

The present invention is not limited to the embodiment described above, and it is obvious that various modifications and combinations can be carried out by a person skilled in the art within the technical idea of the present invention.

### REFERENCE SIGNS LIST

101 Rear DBR region
102 Phase adjustment region
103 Laser active region
104 Front DBR region
105 Amplification region
111 First current injection unit
112 Second current injection unit
113 Third current injection unit
114 Fourth current injection unit.

1-4. (canceled)

5. A wavelength-variable laser, comprising:
a rear DBR region;
a phase adjustment region after the rear DBR region;
a laser active region after the phase adjustment region;
a front DBR region after the laser active region;
an amplification region after the front DBR region;
a first current injection circuit configured to inject a DBR current into the rear DBR region and the front DBR region; and
a second current injection circuit configured to inject a phase adjustment current that changes at a frequency that is twice a frequency of the DBR current into the phase adjustment region in synchronization with the DBR current.

6. The wavelength-variable laser according to claim 5, wherein the first current injection circuit is configured to invert a modulation signal for modulating the DBR current in a region in which the modulation signal is a negative value.

7. A method for controlling a wavelength-variable laser, comprising:
injecting a phase adjustment current that changes at a frequency that is twice a frequency of a DBR current injected into a rear DBR region and a front DBR region into a phase adjustment region in synchronization with the DBR current, wherein the wavelength-variable laser comprising:
the rear DBR region;
the phase adjustment region after the rear DBR region;
a laser active region after the phase adjustment region;
the front DBR region after the laser active region; and
an amplification region after the front DBR region.

8. The method for controlling the wavelength-variable laser according to claim 7, further comprising inverting a modulation signal for modulating the DBR current in a region in which the modulation signal is a negative value.

9. A wavelength-variable laser, comprising:
a rear DBR region;
a phase adjustment region adjacent to the rear DBR region;
a laser active region, wherein the phase adjustment region is between the laser active region and the rear DBR region;
a front DBR region, wherein the laser active region is between the front DBR region and the phase adjustment region;
a first current injection circuit configured to inject a DBR current into the rear DBR region and the front DBR region; and
a second current injection circuit configured to inject a phase adjustment current that changes at a frequency that is twice a frequency of the DBR current into the phase adjustment region in synchronization with the DBR current.

10. The wavelength-variable laser according to claim 9, further comprising an amplification region, wherein the front DBR region is between the amplification region and the laser active region.

11. The wavelength-variable laser according to claim 9, wherein the first current injection circuit is configured to invert a modulation signal for modulating the DBR current in a region in which the modulation signal is a negative value.
